(19) United States
(12) Patent Application Publication
(10) Pub. No.: US 2017/0186926 A1
(43) Pub. Date: Jun. 29, 2017

(54) LIGHT EMITTING DEVICE PACKAGE HAVING ENHANCED LIGHT EXTRACTION EFFICIENCY

(71) Applicant: SAMSUNG ELECTRONICS CO., LTD., Suwon-si (KR)

(72) Inventor: Chi Goo KANG, Yongin-si (KR)

(73) Assignee: SAMSUNG ELECTRONICS CO., LTD., Suwon-si (KR)

(21) Appl. No.: 15/213,770

(22) Filed: Jul. 19, 2016

(30) Foreign Application Priority Data
Dec. 24, 2015 (KR) 10-2015-0185593

(51) Int. Cl. H01L 33/60; H01L 33/52; H01L 33/62; H01L 33/50

(52) U.S. Cl. CPC H01L 33/60; H01L 33/504; H01L 33/52; H01L 33/62

(57) ABSTRACT

A light emitting device package having enhanced light extraction efficiency includes a body having a mounting region, a light emitting device disposed above the mounting region, and a spacer disposed between the light emitting device and the mounting region to secure a space between the light emitting device and the mounting region. The spacer has a reflective surface reflecting light emitted by the light emitting device to the mounting region in a lateral direction.

### CROSS-REFERENCE TO THE RELATED APPLICATION

This application claims priority from Korean Patent Application No. 10-2015-0185593 filed on Dec. 24, 2015 in the Korean Intellectual Property Office, the disclosure of which is incorporated herein by reference in its entirety.

### BACKGROUND

1. Field

Apparatuses consistent with example embodiments of the present inventive concept relate to a light emitting device package having enhanced light extraction efficiency.

2. Description of Related Art

In the case of light emitting device packages of the related art, an LED chip is fixed to the interior of a package by a method of applying an adhesive to an interface between the lower surface of the LED chip and the package so that the LED chip may be mounted on the interior of the package.

As such, when the LED chip is in contact with the package, light emitted through the lower portion of the LED chip is reflected from the package into the LED chip, and thus, may not escape externally due to total internal reflection, thus causing a problem in which light extraction loss occurs. In other words, since the intensity of light emitted after the LED chip is mounted on the interior of the package is less than the intensity of light emitted by the LED chip itself, there may be a problem in which luminous efficiency is reduced.

### SUMMARY

Example embodiments of the present inventive concept provide a light emitting device package having enhanced light extraction efficiency to address a problem in which light extraction efficiency is reduced due to total internal reflection when an LED chip is mounted on an interior of the package.

According to an example embodiment, there is provided a light emitting device package having enhanced light extraction efficiency which may include: a body including a mounting region; a light emitting device disposed above the mounting region; and a spacer disposed between the light emitting device and the mounting region to secure a space between the light emitting device and the mounting region, and having a reflective surface reflecting light emitted by the light emitting device to the mounting region in a lateral direction.

According to an example embodiment, there is provided a light emitting device package which may include: a body having a reflective groove; a spacer disposed on a bottom surface of the reflective groove; a light emitting device disposed on the spacer; and an adhesive surrounding the spacer and fixing the light emitting device to the spacer, wherein the spacer secures a space between the light emitting device and the bottom surface of the reflective groove, and includes a reflective surface laterally reflecting light emitted by the light emitting device to the bottom surface of the reflective groove.

According to an example embodiment, there is provided a light emitting device package which may include: a light emitting device; a body laterally supporting the light emitting device; a lead frame disposed below the light emitting device; and a spacer disposed between the light emitting device and the lead frame, and including a reflective surface reflecting light emitted by the light emitting device to the mounting region in a lateral direction.

### BRIEF DESCRIPTION OF DRAWINGS

The above and other aspects of the present inventive concept will be more clearly understood from the following detailed description taken in conjunction with the accompanying drawings, in which:

FIG. 1 is a schematic perspective view of a light emitting device package having enhanced light extraction efficiency according to an example embodiment;

FIG. 2 is a cross-sectional view of the light emitting device package illustrated in FIG. 1, according to an example embodiment;

FIGS. 3A and 3B are respective schematic cross-sectional views of a spacer in the light emitting device package, according to an example embodiment;

FIG. 4 is a schematic cross-sectional view of a modified example of the spacer, according to an example embodiment;

FIG. 5 is a schematic cross-sectional view of a light emitting device package according to an example embodiment;

FIGS. 6A and 6B are respective schematic cross-sectional views of spacers with respect to the light emitting device package illustrated in FIG. 5, according to example embodiments;

FIG. 7 is a CIE 1931 color space chromaticity diagram illustrating a phosphor employable in an example embodiment;

FIG. 8 is a schematic cross-sectional side view of a light emitting device employable in an example embodiment;

FIG. 9 is a schematic exploded perspective view of a lighting device (a bulb-type lighting device) according to an example embodiment; and

FIG. 10 is a schematic exploded perspective view of a lighting device (an L-type lamp) according to an example embodiment.

### DETAILED DESCRIPTION

Hereinafter, example embodiments of the present inventive concept will be described as follows with reference to the attached drawings.

The present inventive concept may, however, be exemplified in many different forms and should not be construed as being limited to the specific embodiments set forth herein. Rather, these embodiments are provided so that this disclosure will be thorough and complete, and will fully convey the inventive concept to those skilled in the art.

Throughout the specification, it will be understood that when an element, such as a layer, region or wafer (substrate), is referred to as being “on,” “connected to,” or “coupled to” another element, it can be directly “on,” “connected to,” or “coupled to” the other element or other elements intervening therebetween may be present. In contrast, when an element is referred to as being “directly on,” “directly connected to,” or “directly coupled to” another element, there may be no elements or layers intervening therebetween. Like numerals refer to like elements throughout. As used herein, the term “and/or” includes any and all combinations of one or more of the associated listed items.

It will be apparent that though the terms first, second, third, etc. may be used herein to describe various members, components, regions, layers and/or sections, these members, components, regions, layers and/or sections should not be limited by these terms. These terms are only used to distinguish one member, component, region, layer or section from another region, layer or section. Thus, a first member, component, region, layer or section discussed below could be termed a second member, component, region, layer or section without departing from the teachings of the exemplary embodiments.

Spatially relative terms, such as “above,” “upper,” “below,” and “lower” and the like, may be used herein for ease of description to describe one element's relationship to another element(s) as shown in the figures. It will be understood that the spatially relative terms are intended to encompass different orientations of the device in use or operation in addition to the orientation depicted in the figures. For example, if the device in the figures is turned over, elements described as “above,” or “upper” other elements would then be oriented “below,” or “lower” the other elements or features. Thus, the term “above” can encompass both the above and below orientations depending on a particular direction of the figures. The device may be otherwise oriented (rotated 90 degrees or at other orientations) and the spatially relative descriptors used herein may be interpreted accordingly.

The terminology used herein describes particular embodiments only, and the present inventive concept is not limited thereby. As used herein, the singular forms “a,” “an,” and “the” are intended to include the plural forms as well, unless the context clearly indicates otherwise. It will be further understood that the terms “comprises,” and/or “comprising” when used in this specification, specify the presence of stated features, integers, steps, operations, members, elements, and/or groups thereof, but do not preclude the presence or addition of one or more other features, integers, steps, operations, members, elements, and/or groups thereof.

Hereinafter, example embodiments of the present inventive concept will be described with reference to schematic views illustrating the embodiments of the present inventive concept. In the drawings, for example, due to manufacturing techniques and/or tolerances, modifications of the shape shown may be estimated. Thus, the example embodiments of the present inventive concept should not be construed as being limited to the particular shapes of regions shown herein, for example, to include a change in shape results in manufacturing. The following example embodiments may also be constituted as one or a combination thereof.

The contents of the present inventive concept described below may have a variety of configurations and propose only a required configuration herein, but are not limited thereto.

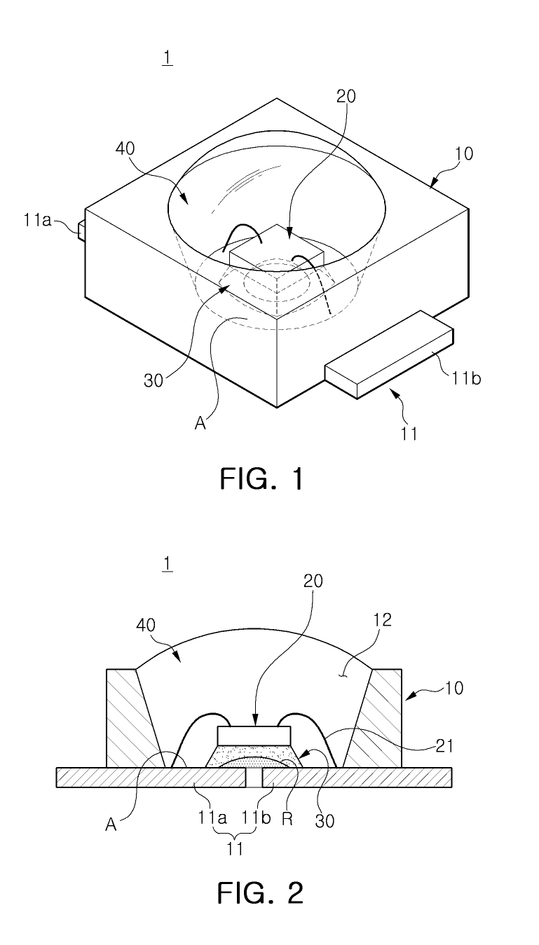

With reference to FIGS. 1 and 2, a light emitting device package having enhanced light extraction efficiency according to an example embodiment of the present inventive concept is described. FIG. 1 is a schematic perspective view of the light emitting device package having enhanced light extraction efficiency according to an example embodiment, and FIG. 2 is a cross-sectional view of the light emitting device package illustrated in FIG. 1.

With reference to FIGS. 1 and 2, a light emitting device package having enhanced light extraction efficiency 1 according to an example embodiment may include a body 10, a light emitting device 20, and a spacer 30. The light emitting device package 1 may further include an encapsulator 40.

The body 10 may be provided as a base member which supports the light emitting device 20 mounted thereon.

The body 10 may be formed using a white molding compound having a high degree of light reflectivity. Thus, an amount of light emitted externally may be increased by allowing light emitted by the light emitting device 20 to be reflected thereby.

The white molding compound may include a thermosetting resin-based material having high heat resistance or a silicon resin-based material. In addition, a white pigment, a filling material, a hardener, a mold release agent, an antioxidant, an adhesion improver, or the like may be added to a thermoplastic resin-based material. Furthermore, the body 10 may also be formed using FR-4, CEM-3, an epoxy material, a ceramic material, or the like. The body 10 may also be formed using a metal.

The body 10 may be provided with lead frames 11 to be electrically connected to an external power supply. The lead frames 11 may be formed using a material having excellent electrical conductivity, for example, a metal such as aluminum (Al), silver (Ag), copper (Cu), or the like.

The lead frames 11 may be formed by at least a pair of lead frames disposed in a manner of being separated from and opposing each other and electrically insulated from each other. For example, the lead frames 11 may include a first lead frame 11a having a first polarity and a second lead frame 11b having a second polarity different from the first polarity. In this case, the first polarity and the second polarity may be positive and negative respectively, (or vice versa). In addition, the first lead frame 11a and the second lead frame 11b may be separated from each other to be electrically insulated by the body 10.

Bottom surfaces of the first and second lead frames 11a and 11b may be externally exposed through a bottom surface of the body 10. Thus, heat generated by the light emitting device 20 may be easily emitted externally, thus increasing heat radiation efficiency.

The body 10 may include a reflective groove 12 recessed to a predetermined depth in an upper portion therein. The reflective groove 12 may have a cup structure tapered inwardly, and an interior surface thereof may be inclined inwardly toward the bottom surface of the body 10. Additionally, a bottom surface of the reflective groove 12 may be defined as a mounting region A on which the light emitting device 20 is disposed.

The first and second lead frames 11a and 11b may be partially exposed on the bottom surface of the reflective groove 12. The light emitting device 20 may be electrically connected to the first and second lead frames 11a and 11b by a wire 21.

The light emitting device 20 may be disposed above the mounting region A. The light emitting device 20 may be an optoelectronic device generating light having a predetermined wavelength by driving power externally supplied through the lead frames 11. For example, the light emitting device 20 may include a semiconductor light emitting diode (LED) chip having first and second conductivity-type semiconductor layers and an active layer interposed therebetween.

The light emitting device 20 may emit blue, green, or red light depending on a material contained therein or depending on a combination thereof with a phosphor, and may also emit white light, ultraviolet light, or the like.

A detailed configuration and structure of the light emitting device 20 will be described in detail later.

The spacer 30 may be interposed between the light emitting device 20 and the mounting region A to secure a space therebetween. That is, the light emitting device 20 may be spaced apart from the mounting region A by the spacer 30 to be disposed above the mounting region A.

The spacer 30 may include a reflective surface R reflecting light emitted by the light emitting device 20 toward the mounting region A at least in a lateral direction.

A detailed configuration and structure of the spacer 30 will be described in detail later.

The encapsulator 40 may cover the light emitting device 20 and the spacer 30. The encapsulator 40 may be formed of a transparent or semi-transparent material, for example a resin such as silicon, epoxy, or the like, to enable light generated by the light emitting device 20 to be emitted externally.

In the example embodiment, the encapsulator 40 is illustrated as having a lens structure having a form of a protruding dome, but is not limited thereto. The encapsulator 40 may be formed to be planar corresponding to an upper surface of the body 10. Furthermore, an additional lens may be mounted on the upper surface of the encapsulator 40.

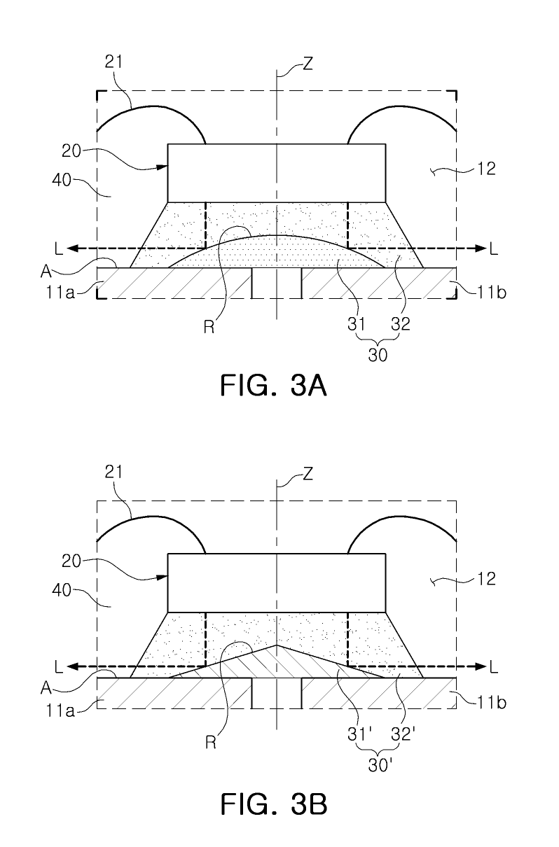

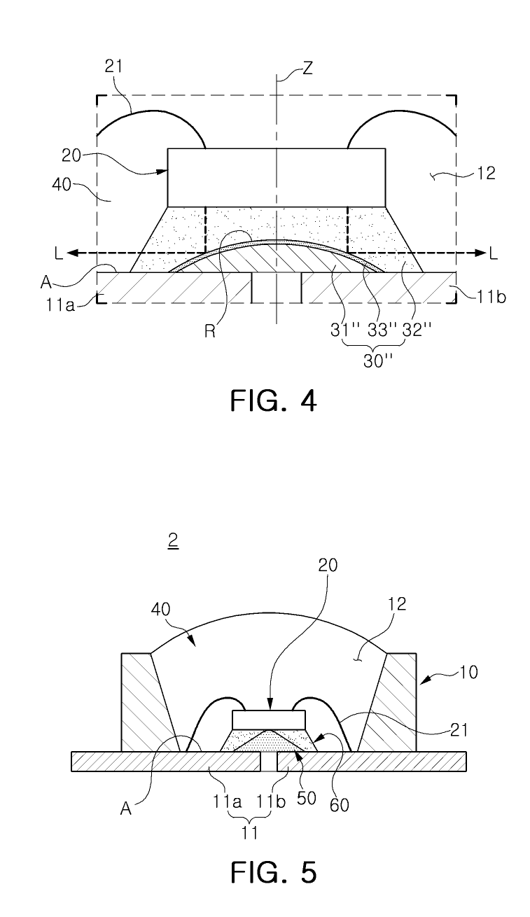

With reference to FIGS. 3A, 3B, and 4, the spacer is described in more detail. FIGS. 3A and 3B are respective schematic cross-sectional views of the spacer in the light emitting device package, and FIG. 4 is a schematic cross-sectional view of a modified example of the spacer.

With reference to FIGS. 3A and 3B, the spacer 30 may include a first layer 31 disposed on the mounting region A and a second layer 32 covering the first layer 31, and may have a structure in which the first and second layers 31 and 32 are stacked on the mounting region A. Additionally, the spacer 30 may include the reflective surface R disposed between the first layer 31 and the second layer 32.

The first layer 31 may have a structure in which a center portion through which an optical axis Z of the light emitting device 20 passes protrudes toward the light emitting device 20. Thus, in the first layer 31, the center portion through which the optical axis Z of the light emitting device 20 passes may be higher from the mounting region A than an edge of the first layer 31 contacting the mounting region A.

A surface of the first layer 31 may include a curved surface or an inclined surface of which a height is decreased from the center portion through which the optical axis Z passes, toward the edge.

The second layer 32 may cover the first layer 31 on the mounting region A. The light emitting device 20 may be disposed on an upper surface of the second layer 32. The second layer 32 may allow the light emitting device 20 to be fixedly disposed above the mounting region A. For example, the second layer 32 may function as an adhesive.

A material forming the first and second layers 31 and 32 may include a light transmissive material. In this case, the first layer 31 and the second layer 32 may have different refractive indices, respectively. For example, when the first layer 31 has a first refractive index, and the second layer 32 has a second refractive index, the second refractive index may be higher than the first refractive index. In this case, an interface between the first layer 31 and the second layer 32 may be defined as the reflective surface R.

Light L of the light emitting device 20 may pass through the second layer 32 having a relatively high refractive index while travelling toward the first layer 31 having a relatively low refractive index, to be reflected from the interface between the first and second layers 31 and 32 and travel in a direction lateral to the spacer 30.

In FIG. 3B, a modified example of a spacer 30′ is illustrated. With reference to FIG. 3B, a second layer 32′ may include a light transmissive material, while a first layer 31′ may include a light reflective material. For example, the second layer 32′ may be formed of a resin such as silicon, epoxy, or the like, and the first layer 31′ may be formed of a white molding compound the same as that of the body 10. In this case, a surface of the first layer 31′ may be defined as a reflective surface R.

Light L of the light emitting device 20 may pass through the second layer 32′ to travel toward the first layer 31′, be reflected from the surface of the first layer 31′, and travel in a direction lateral to the spacer 30′.

With reference to FIG. 4, a spacer 30″ may include a reflective film 33″ covering a surface of a first layer 31″. In this case, a surface of the reflective film 33″ may be defined as a reflective surface R.

The reflective film 33″ may be formed to cover the surface of the first layer 31″ through a method such as a coating, deposition, attachment method, or the like, using a material having a relatively high degree of reflectivity.

Light L of the light emitting device 20 may pass through the second layer 32″, travel toward the first layer 31″, be reflected from the reflective film 33″ covering the surface of the first layer 31″, and travel in a direction lateral to the spacer 30″.

At least one of the first and second layers 31 and 32 may include one or more types of phosphor. However, in a case where the first layer 31 is formed of a light reflective material or a reflective film 33 is formed on a surface of the first layer 31, a phosphor may be included in the second layer 32.

The phosphor may be excited by light L generated by the light emitting device 20, whereby light having a different wavelength may be emitted therefrom.

For example, when the light emitting device 20 emits blue light, white light may be emitted through combination of yellow, green, red and/or orange phosphors. In addition, the light emitting device 20 may be configured to include at least one of light emitting devices emitting violet, blue, green, red, or infrared light. In this case, a color rendering index (CRI) of the light emitting device 20 may be controlled to be within a range of about 40 to about 100. Furthermore, the light emitting device 20 may generate various types of white light having color temperatures in a range of around 2000 K to around 20000 K. Also, if necessary, the light emitting device 20 may generate visible violet, blue, green, red, orange or infrared light to adjust the color of light in consideration of a surrounding atmosphere and a desired user mood. In addition, the light emitting device 20 may also generate a specific wavelength of light for promoting plant growth.

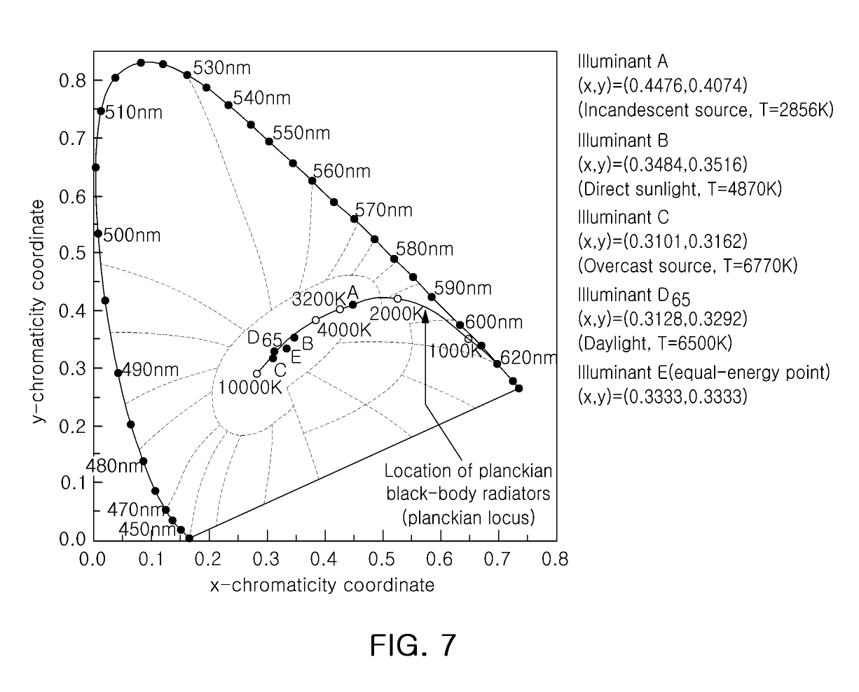

White light generated by combination of yellow, green, and red phosphors and a blue light emitting device and/or through combination of the blue light emitting device and green and red light emitting devices may have two or more peak wavelengths. Additionally, coordinates (x, y) thereof in a CIE 1931 color space chromaticity diagram illustrated in FIG. 7 may be positioned on a line segment connecting coordinates (0.4476, 0.4074), (0.3484, 0.3516), (0.3101, 0.3162), (0.3128, 0.3292), and (0.3333, 0.3333). Alternatively, the coordinates (x, y) thereof in the CIE 1931 color space chromaticity diagram may be positioned in a region surrounded by the line segment and a blackbody radiation spectrum. A color temperature of the white light may range from about 2,000 K to about 20,000 K.

In FIG. 7, white light in the vicinity of point E (0.3333, 0.3333) disposed below the blackbody radiation spectrum may be in a state in which a level of yellow light is relatively low, and may be used as a lighting light source in a region exhibiting brighter or fresher feeling to a naked eye. Therefore, lighting products using white light in the vicinity of point E (0.3333, 0.3333) disposed below the blackbody radiation spectrum may be highly effective as a lighting device for retail spaces in which consumer goods are offered for sale.

The phosphors may have the following empirical formulas and colors.

Oxides: yellow and green Y₃Al₅O₁₂:Ce, Tb₃Al₅O₁₂:Ce, Lu₃Al₅O₁₂:Ce

Silicates: yellow and green (Ba,Sr)₂SiO₄:Eu, yellow and orange (Ba,Sr)₃SiO₅:Ce

Nitrides: green β-SiAlON:Eu, yellow La₃Si₆N₁₁:Ce, orange α-SiAlON:Eu, red CaAlSiN₃:Eu, Sr₂Si₅N₈:Eu, SrSiAl₄N₇:Eu, SrLiAl₃N₄:Eu, Ln₄₋ₓ(Eu_{z}M_{1-z})ₓSi_{12-y}Al_{y}O_{3+x+y}N_{18-x-y} (0.5≦x≦3, 0<z<0.3, 0<y≦4) (where, Ln is at least one element selected from a group consisting of group IIIa elements and rare-earth elements, and M is at least one element selected from a group consisting of Ca, Ba, Sr and Mg)

Fluorides: KSF-based red K₂SiF₆:Mn⁴⁺, K₂TiF₆:Mn⁴⁺, NaYF₄:Mn⁴⁺, NaGdF₄:Mn⁴⁺ and K₃SiF₇:Mn⁴⁺

Phosphor compositions should basically conform to stoichiometry, and respective elements may be substituted with other elements of respective groups of the periodic table. For example, strontium (Sr) may be substituted with barium (Ba), calcium (Ca), magnesium (Mg), and the like within the alkaline earth group (II), and yttrium (Y) may be substituted with lanthanum (La)-based elements such as terbium (Tb), lutetium (Lu), scandium (Sc), gadolinium (Gd), and the like. Also, europium (Eu), an activator, may be substituted with cerium (Ce), terbium (Tb), praseodymium (Pr), erbium (Er), ytterbium (Yb), and the like, in consideration of a desired energy level, and an activator may be applied alone or with a co-activator for modifying the characteristics of phosphors.

In detail, in order to enhance reliability at high temperatures and high levels of humidity, a fluoride-based red phosphor may be coated with a fluoride not containing manganese (Mn) or organic materials thereon. The organic materials may be coated on the fluoride-based red phosphor coated with a fluoride not containing manganese (Mn). Unlike other phosphors, the fluoride-based red phosphor may implement a narrow full width at half maximum (FWHM) equal to or less than 40 nm, and thus, it may be used in a high resolution TV such as an ultra-high definition (UHD) TV.

Further, as a material to be substituted for the phosphor, a quantum dot (QD) or the like may be used in the wavelength conversion material, and the QD may be used alone or in combination with the phosphor.

The QD may have a core-shell structure using group III-V or group II-VI compound semiconductor. For example, the QD may have a core such as CdSe or InP or a shell such as ZnS or ZnSe. In addition, the QD may include a ligand to stabilize the core and shell. For example, the core may have a diameter in a range of about 1 nm to about 30 nm, in detail, about 3 nm to about 10 nm. The shell may have a thickness in a range of about 0.1 nm to about 20 nm, in detail, about 0.5 nm to about 2 nm.

The QD may implement various colors of light depending on a size thereof and, for example, when the QD is used as a phosphor substitute, it may be substituted for a red or a green phosphor. When the QD is used, a narrow full width at half maximum (for example, about 35 nm) may be implemented.

In the meantime, at least one of the first and second layers 31 and 32 may include a light dispersant. However, in a case in which the first layer 31 is formed of a light reflective material or the reflective film 33 is formed on the surface of the first layer 31, the light dispersant may be included in the second layer 32.

For example, the light dispersant may include at least one of SiO₂, Al₂O₃, and TiO₂.

As such, the light emitting device 20 may be disposed to be spaced apart from the mounting region A by a predetermined interval by the spacer 30 interposed between the light emitting device 20 and the mounting region A of the body 10.

In other words, securing a space for light extraction between the light emitting device 20 and the mounting region A through the spacer 30 enables light L emitted through a lower portion of the light emitting device 20 not to be reflected toward the interior thereof, but in a lateral direction, thereby improving light extraction efficiency. Thus, a problem of light extraction loss occurring due to light emitted through the lower portion of the light emitting device being totally internally reflected therein and not escaping externally due to total internal reflection therein as in the related art light emitting device may be resolved.

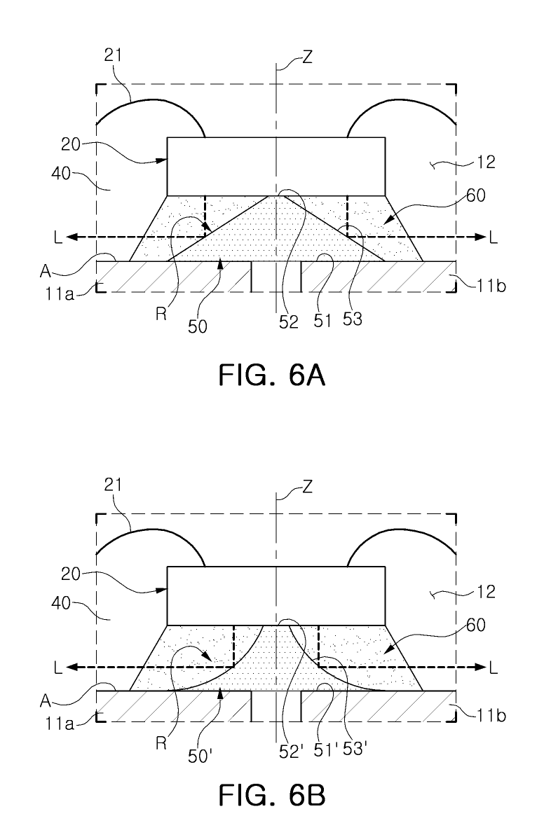

With reference to FIGS. 5, 6A, and 6B, the light emitting device package according to an example embodiment of the present inventive concept is described. FIG. 5 is a schematic cross-sectional view of the light emitting device package according to an example embodiment, and FIGS. 6A and 6B are respective schematic cross-sectional views of spacers with respect to the light emitting device package illustrated in FIG. 5.

With reference to FIG. 5, a light emitting device package 2 according to an example embodiment may include a body 10, a light emitting device 20, a spacer 50, and an adhesive 60. The light emitting device package 2 may further include an encapsulator 40.

A configuration of the light emitting device package 2 according to example embodiments illustrated in FIGS. 5 to 6B has substantially the same basic structure as that of the light emitting device package 1 according to the example embodiments illustrated in FIGS. 1 to 4. However, since a structure of the spacer 50 is different from that of the example embodiments illustrated in FIGS. 1 to 4, hereinafter, a description substantially identical to the foregoing detailed example embodiments will be omitted, and a difference will be primarily described.

With reference to FIGS. 5 to 6B, the body 10 may include a reflective groove 12, and the spacer 50 may be disposed on a bottom surface of the reflective groove 12. The light emitting device 20 may be disposed on the spacer 50 to be spaced apart from the bottom surface of the reflective groove 12 by an interval equal to a distance between the bottom surface of the reflective groove 12 and a top of the spacer 50. The light emitting device 20 may be electrically connected to the first and second lead frames 11a and 11b exposed to the reflective groove 12 by the wire 21.

The spacer 50 may secure a space between the light emitting device 20 and the bottom surface of the reflective groove 12.

The spacer 50 may have a structure in which a center portion thereof through which an optical axis Z of the light emitting device 20 passes protrudes toward the light emitting device 20. In this case, the spacer 50 may have a structure in which the center portion is generally pointed to significantly reduce a contact area with the light emitting device 20.

In detail, the spacer 50 may include a lower surface 51 contacting the bottom surface of the reflective groove 12, an upper surface 52 contacting the lower portion of the light emitting device 20, and a side surface 53 connecting the lower surface 51 to the upper surface 52.

The upper surface 52 may have a cross-sectional area smaller than that of the lower surface 51. In detail, the upper surface 52 may have a relatively small cross-sectional area to significantly reduce a contact area with a lower surface of the light emitting device 20.

The side surface 53 may have an inclined structure in a linear shape. The side surface 53 may be defined as the reflective surface R reflecting light L traveling from the lower surface of the light emitting device 20 toward the bottom surface of the reflective groove 12 in a lateral direction.

In addition, as illustrated in FIG. 6B, a spacer 50′ may include a lower surface 51′, an upper surface 52′, and a side surface 53′, and the side surface 53′ may include an inclined structure in a curved shape which may be concave toward a center of the lower surface 51′. The side surface 53′ may be defined as a reflective surface R reflecting light L traveling from the lower surface of the light emitting device 20 toward the bottom surface of the reflective groove 12 in a lateral direction.

Directions of light L reflected in a direction lateral to the spacer 50′ may be variously adjusted through various changes in curvature of the side surface 53′.

The spacer 50 may be formed of a white molding compound having a relatively high degree of light reflectivity as in the body 10, but is not limited thereto. For example, the spacer 50 may be formed of a different material including a metal, or the like.

The light emitting device 20 may be fixed to the spacer 50 by the adhesive 60 surrounding the spacer 50. The adhesive 60 may have light transmissive properties to enable light reflected by the spacer 50 to be emitted externally.

The encapsulator 40 filling the reflective groove 12 may cover the light emitting device 20, the spacer 50, and the adhesive 60. The encapsulator 40 may be formed of a transparent or semi-transparent material, for example, a resin such as silicon, epoxy, or the like, to enable light generated by the light emitting device 20 to be emitted externally.

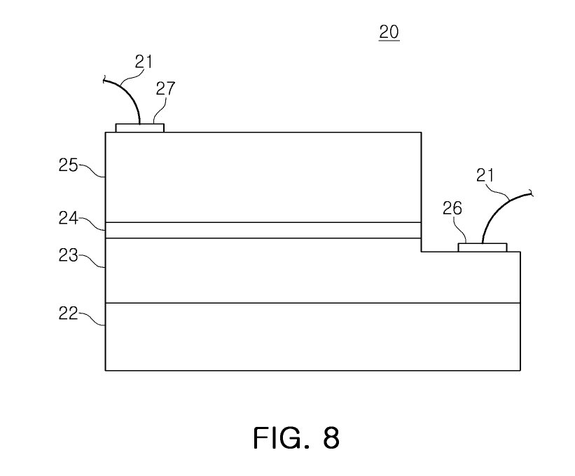

FIG. 8 is a schematic view of the light emitting device. FIG. 8 is a schematic cross-sectional side view of a light emitting device employable in an example embodiment of the present inventive concept.

For example, as illustrated in FIG. 8, the light emitting device 20 may have a stacked structure in which a first conductivity-type semiconductor layer 23, a second conductivity-type semiconductor layer 25, and an active layer 24 interposed therebetween are stacked, but is not limited thereto.

The first conductivity-type semiconductor layer 23 disposed on a growth substrate 22 having light transmissive properties may include a semiconductor doped with an n-type impurity, and may include an n-type nitride semiconductor layer. The second conductivity-type semiconductor layer 25 may include a semiconductor doped with a p-type impurity, and may include a p-type nitride semiconductor layer. However, in example embodiments, stacking positions of the first and second conductivity-type semiconductor layers 23 and 25 may be inverted.

For example, the first and second conductivity-type semiconductor layers 23 and 25 may have a material represented by empirical formula AlₓIn_{y}Ga_{(1-x-y)}N (0≦x<1, 0≦y<1, 0x+y<1), such as, GaN, AlGaN, InGaN, AlInGaN, or the like.

The active layer 24 interposed between the first and second conductivity-type semiconductor layers 23 and 25 may emit light having a predetermined level of energy through recombination of an electron and a hole. The active layer 24 may include a material having an energy band gap smaller than those of the first and second conductivity-type semiconductor layers 23 and 25. For example, when the first and second conductivity-type semiconductor layers 23 and 25 are GaN compound semiconductors, the active layer 24 may include an InGaN compound semiconductor having an energy band gap smaller than that of GaN.

In addition, the active layer 24 may be formed in a structure of a multiple quantum well (MQW) in which a quantum well layer and a quantum barrier layer are alternately stacked, for example, an InGaN/GaN structure, but is not limited thereto. Thus, a single quantum well (SQW) structure may be used in the active layer 24.

A first electrode pad 26 may be disposed on an exposed surface of the first conductivity-type semiconductor layer 23 formed by allowing the second conductivity-type semiconductor layer 25, the active layer 24, and portions of the first conductivity-type semiconductor layer 23 to be etched, to thus be connected to the first conductivity-type semiconductor layer 23. A second electrode pad 27 may be disposed on an upper surface of the second conductivity-type semiconductor layer 25 to be connected thereto.

The first and second electrode pads 26 and 27 may be connected to the first and second lead frames 11a and 11b , respectively, by the wire 21.

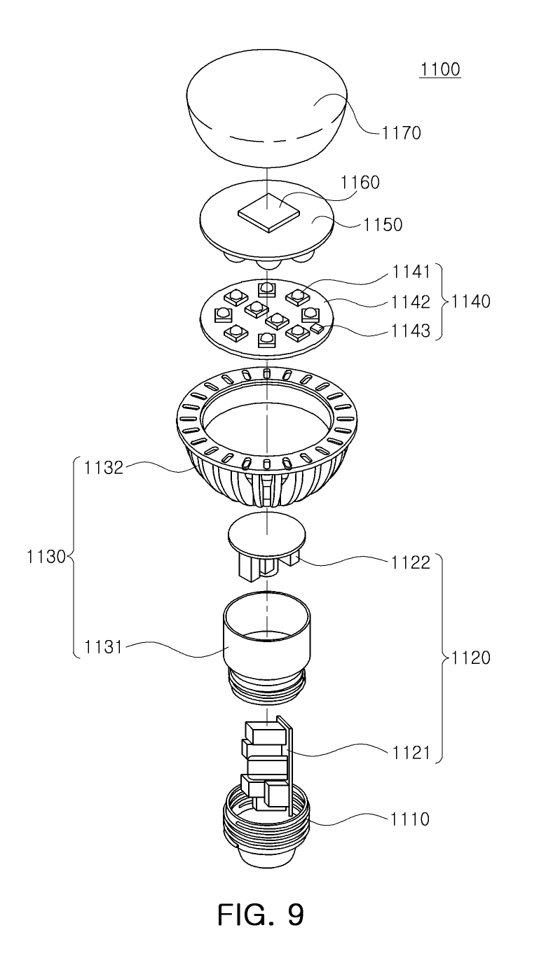

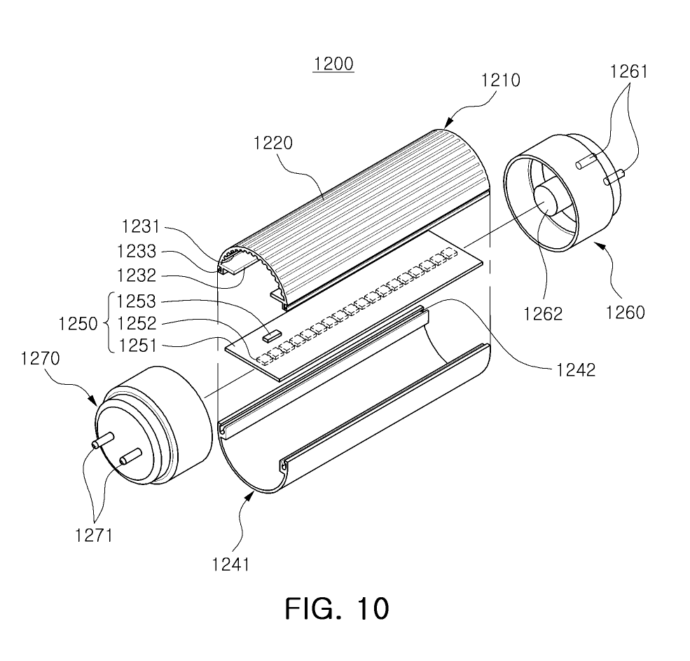

With reference to FIGS. 9 and 10, various lighting devices employing a light emitting device package according to example embodiments of the present inventive concept are described.

FIG. 9 is a schematic exploded perspective view of a bulb-type lamp, a lighting device, according to example embodiments.

With reference to FIG. 9, a lighting device 1100 may include a screw cap 1110, a power supply unit 1120, a heat radiating unit 1130, a light source unit 1140, and an optical unit 1170. According to an example embodiment of the present inventive concept, the light source unit 1140 may include a substrate 1142, a plurality of light emitting device packages 1141 mounted on the substrate 1142, and a controller 1143, while the controller 1143 may store driving information of the plurality of the light emitting device packages 1141 therein.

A reflector 1150 may be disposed over the light source unit 1140, and may enable light emitted by the light source unit 1140 to be uniformly dispersed laterally and backwardly, thereby reducing glare.

A communications module 1160 may be mounted on the reflector 1150, and may allow home-network communications to be implemented. For example, the communications module 1160 may be a wireless communications module using Zigbee®, Wi-Fi, or Li-Fi, and may control lighting installed in the interior and on the exterior of a home by turning a lighting device on or off and adjusting a level of brightness thereof through a smartphone or a wireless controller. In addition, an electronic product in the interior and on the exterior of a home, such as a TV, a refrigerator, an air conditioner, a door lock, or the like as well as an automobile or an automotive system may be controlled through the Li-Fi communications module using a visible wavelength of light of a lighting device installed in the interior and on the exterior of a home.

The reflector 1150 and the communications module 1160 may be covered by the cover unit 1170.

The screw cap 1110 may be configured to be compatible with a screw cap of an existing lighting apparatus. Power supplied to the lighting device 1100 may be applied through the screw cap 1110. As illustrated, the power supply unit 1120 may include a first power supply portion 1121 and a second power supply portion 1122 separated from and coupled to each other.

The heat radiating unit 1130 may include an internal heat radiating portion 1131 and an external heat radiating portion 1132. In addition, the internal heat radiating portion 1131 may be directly connected to the light source unit 1140 and/or the power supply unit 1120, by which heat may be transferred to the external heat radiating portion 1132.

The optical unit 1170 may include an internal optical portion (not illustrated) and an external optical portion (not illustrated), and may be configured to allow light emitted by the light source unit 1140 to be uniformly dispersed.

The plurality of light emitting device packages 1141 of the light source unit 1140 may be supplied with electrical power from the power supply unit 1120, and may emit light to the optical unit 1170. In the example embodiment, the light emitting device package 1141 may have a structure substantially corresponding to the light emitting device packages 1 and 2 illustrated in FIGS. 1 to 6. Thus, a detailed description of respective constituent elements of the light emitting device package 1141 can be understood with reference to the example embodiment.

FIG. 10 is a schematic exploded perspective view of a bar-type lamp, a lighting device, according to example embodiments.

With reference to FIG. 10, a lighting device 1200 may include a heat radiating member 1210, a cover 1241, a light source module 1250, a first socket 1260, and a second socket 1270.

A plurality of heat radiating fins 1220 and 1231 having a concave-convex form may be formed on an inner surface and/or an external surface of the heat radiating member 1210, and the heat radiating fins 1220 and 1231 may be designed to have various forms and intervals therebetween.

A support portion 1232 having a protruding form may be formed inwardly of the heat radiating member 1210. The light source module 1250 may be fixed to the support portion 1232. A stop protrusion 1233 may be formed on opposing ends of the heat radiating member 1210.

The cover 1241 may include a stop groove 1242 formed therein, and the stop groove 1242 may be coupled to the stop protrusion 1233 of the heat radiating member 1210 in a hook coupling structure. Positions in which the stop groove 1242 and the stop protrusion 1233 are formed may be inverted.

The light source module 1250 may include a light emitting device package array. The light source module 1250 may include a printed circuit board 1251, a light emitting device package 1252, and a controller 1253. As described above, the controller 1253 may store driving information of the light emitting device package 1252. The printed circuit board 1251 may be provided with circuit wirings formed therein to operate the light emitting device package 1252. In addition, constituent elements to operate the light emitting device package 1252 may be provided. The light emitting device package 1252 is substantially the same as the light emitting device packages 1 and 2 illustrated in FIGS. 1 to 6. Thus, a detailed description thereof will be omitted.

The first and second sockets 1260 and 1270 may be provided as a pair of sockets, and may have a structure in which they are coupled to opposing ends of a cylindrical cover unit configured of the heat radiating member 1210 and the cover 1241. For example, the first socket 1260 may include an electrode terminal 1261 and a power supply device 1262, and the second socket 1270 may include a dummy terminal 1271 disposed thereon. In addition, an optical sensor and/or a communications module may be disposed inside one of the first socket 1260 or the second socket 1270. For example, the optical sensor and/or the communications module may be installed within the second socket 1270 in which the dummy terminal 1271 is disposed. As another example, an optical sensor and/or a communications module may be installed within the first socket 1260 in which the electrode terminal 1261 is disposed.

A lighting device using a light emitting device may be largely classified as an indoor LED lighting device and an outdoor LED lighting device. The indoor LED lighting device may mainly be used in a bulb-type lamp, an LED-tube lamp, or a flat-type lighting device, as an existing lighting device retrofit, and the outdoor LED lighting device may be used in a streetlight, a safety lighting fixture, a light transmitting lamp, a landscape lamp, a traffic light, or the like.

In addition, a lighting device using LEDs may be utilized as internal and external light sources in vehicles. As the internal light source, the lighting device using LEDs may be used as interior lights for motor vehicles, reading lamps, various types of light source for an instrument panel, and the like, and as the external light sources used in vehicles, the lighting device using LEDs may be used in all types of light sources such as headlights, brake lights, turn signal lights, fog lights, running lights for vehicles, and the like.

Furthermore, LED lighting devices may be used as light sources in robots or in various kinds of mechanical equipment. In detail, an LED lighting device using light within a special wavelength band may promote plant growth, may stabilize people's moods, or may also be used therapeutically, as emotional lighting.

As set forth above, according to example embodiments of the present inventive concept, a light emitting device package having enhanced light extraction efficiency, resolving a problem in which light extraction efficiency is reduced due to total internal reflection with an LED chip mounted to an inside of the package may be provided.

While example embodiments have been shown and described above, it will be apparent to those skilled in the art that modifications and variations could be made without departing from the scope of the present inventive concept as defined by the appended claims.

What is claimed is:

1. A light emitting device package comprising:
a body comprising a mounting region;
a light emitting device disposed above the mounting region; and
a spacer disposed between the light emitting device and the mounting region to secure a space between the light emitting device and the mounting region, and comprising a reflective surface reflecting light emitted by the light emitting device to the mounting region in a lateral direction.

2. The light emitting device package of claim 1, wherein the spacer comprises a first layer disposed on the mounting region, a second layer covering the first layer, and the reflective surface disposed between the first layer and the second layer.

3. The light emitting device package of claim 2, wherein the first layer has a structure in which a center portion through which an optical axis of the light emitting device passes protrudes toward the light emitting device.

4. The light emitting device package of claim 2, wherein the first layer has a structure in which the center portion through which the optical axis of the light emitting device passes is higher from the mounting region than an edge of the first layer contacting the mounting region.

5. The light emitting device package of claim 2, wherein the first layer has a first refractive index, and the second layer has a second refractive index which is higher than the first refractive index.

6. The light emitting device package of claim 2, wherein the second layer comprises a light transmissive material, and the first layer includes a light reflective material.

7. The light emitting device package of claim 2, wherein at least one of the first and second layers comprises one or more types of phosphor.

8. The light emitting device package of claim 2, wherein at least one of the first and second layers comprises a light dispersant.

9. The light emitting device package of claim 2, wherein the reflective surface comprises an interface between the first and second layers.

10. The light emitting device package of claim 2, further comprising a reflective film covering a surface of the first layer.

11. The light emitting device package of claim 1, further comprising an encapsulator covering the light emitting device and the spacer.

12. A light emitting device package comprising:
a body having a reflective groove;
a spacer disposed on a bottom surface of the reflective groove;
a light emitting device disposed on the spacer; and
an adhesive surrounding the spacer and fixing the light emitting device to the spacer,
wherein the spacer secures a space between the light emitting device and the bottom surface of the reflective groove, and comprises a reflective surface laterally reflecting light emitted by the light emitting device to the bottom surface of the reflective groove.

13. The light emitting device package of claim 12, wherein the spacer has a structure in which a center portion through which an optical axis of the light emitting device passes protrudes toward the light emitting device.

14. The light emitting device package of claim 12, wherein the spacer comprises an inclined side surface which forms the reflective surface.

15. The light emitting device package of claim 12, wherein the spacer comprises a curved side surface which forms the reflective surface.

16. The light emitting device package of claim 12, further comprising an encapsulator filling the reflective groove.

17. A light emitting device package comprising:
a light emitting device;
a body laterally supporting the light emitting device;
a lead frame disposed below the light emitting device; and
a spacer disposed between the light emitting device and the lead frame, and comprising a reflective surface reflecting light emitted by the light emitting device in a lateral direction.

18. The light emitting device package of claim 17, wherein the reflective surface comprises at least one of a curved structure and an inclined structure on which light emitted from a bottom of the light emitting device is reflected to be directed toward a side of the spacer.

19. The light emitting device package of claim 18, wherein the spacer comprises a first layer and a second layer having different reflective indices, and
wherein the reflective surface is disposed between the first layer and the second layer.

20. The light emitting device package of claim 18, further comprising an adhesive surrounding the spacer and fixing the light emitting device to the spacer.
